(19) United States
(12) Patent Application Publication
(10) Pub. No.: US 2020/0064411 A1
(43) Pub. Date: Feb. 27, 2020

(54) MOBILE PLATFORM, COMPUTER READABLE STORAGE MEDIUM, BATTERY AND CONTROL METHOD AND SYSTEM THEREOF

(71) Applicant: SZ DJI TECHNOLOGY CO., LTD., Shenzhen (CN)

(72) Inventors: Yangyang TANG, Shenzhen (CN); Mayue CHEN, Shenzhen (CN); Dayang ZHENG, Shenzhen (CN); Wentao WANG, Shenzhen (CN); Jie TIAN, Shenzhen (CN)

(21) Appl. No.: 16/665,699

(22) Filed: Oct. 28, 2019

Related U.S. Application Data
(63) Continuation of application No. PCT/CN2017/082178, filed on Apr. 27, 2017.

(51) Int. Cl. G01R 31/392; G01R 31/387; G01R 31/3842; H02J 7/00

(52) U.S. Cl. CPC G01R 31/392; H02J 7/0029; G01R 31/3842; G01R 31/387

(57) ABSTRACT

A battery includes a housing, an electrical energy storage unit mounted inside the housing, and a battery control system electrically coupled to the electrical energy storage unit to control charge and discharge of the electrical energy storage unit. The battery control system includes one or more processors configured to obtain one or more electrical parameters of the battery in a storage state, determine whether the battery is damaged or abnormal according to the one or more electrical parameters of the battery, and automatically discharge the battery to a safe state in response to determining that the battery is damaged or abnormal.

### CROSS-REFERENCE TO RELATED APPLICATION

This application is a continuation application of International Application No. PCT/CN2017/082178, filed on Apr. 27, 2017, the entire content of which is incorporated herein by reference.

### TECHNICAL FIELD

The present disclosure relates to the technical field of battery control and, more particularly, to a mobile platform, a computer readable storage medium, a battery and a control method and system thereof.

### BACKGROUND

With the rapid development of science and technology, mobile platforms or smart terminals are becoming more and more mature, and the degree of intelligence is getting higher and higher. The mobile platforms and smart terminals generally have the mobility feature. In order to ensure the convenience and reliability of the mobile platforms or smart terminals, batteries are often used to provide power for the mobile platforms or smart terminals to ensure a normal use of the mobile platforms or smart terminals.

However, corrosion damage or abnormal operation of the battery generally occurs with an increase of a battery life. If the battery is continuously used to provide power to the mobile platforms or smart terminals, it can easily cause fires and damage the mobile platforms or smart terminals. Not only poses a threat to a personal safety of a user, but also causes a large economic loss to the user.

### SUMMARY

In accordance with the disclosure, there is provided a battery including a housing, an electrical energy storage unit mounted inside the housing, and a battery control system electrically coupled to the electrical energy storage unit to control charge and discharge of the electrical energy storage unit. The battery control system includes one or more processors configured toobtain one or more electrical parameters of the battery in a storage state, determine whether the battery is damaged or abnormal according to the one or more electrical parameters of the battery, and automatically discharge the battery to a safe state in response to determining that the battery is damaged or abnormal.

Also in accordance with the disclosure, there is provided a mobile platform including a motor and a battery configured to power the motor. The battery includes a housing, an electrical energy storage unit mounted inside the housing, and a battery control system electrically coupled to the electrical energy storage unit to control charge and discharge of the electrical energy storage unit. The battery control system includes one or more processors configured toobtain one or more electrical parameters of the battery in a storage state, determine whether the battery is damaged or abnormal according to the one or more electrical parameters of the battery, and automatically discharge the battery to a safe state in response to determining that the battery is damaged or abnormal.

### BRIEF DESCRIPTION OF THE DRAWINGS

In order to provide a clearer illustration of technical solutions of disclosed embodiments, the drawings used in the description of the disclosed embodiments are briefly described below. It will be appreciated that the disclosed drawings are merely examples. Other drawings can be conceived by those having ordinary skills in the art on the basis of the disclosed drawings without inventive efforts.

FIG. 1 is a schematic flow chart of an example battery control method consistent with embodiments of the disclosure.

FIG. 2 is a schematic flow chart of determining whether a battery is damaged or abnormal according to one or more electrical parameters of the battery consistent with embodiments of the disclosure.

FIG. 3 is a schematic flow chart of determining whether a battery is damaged or abnormal according to a voltages of an electrical energy storage unit and a voltage change rate of the battery consistent with embodiments of the disclosure.

FIG. 4 is another schematic flow chart of determining whether a battery is damaged or abnormal according to one or more electrical parameters of the battery consistent with embodiments of the disclosure.

FIG. 5 is a schematic flow chart of obtaining one or more electrical parameters of a battery in a storage state consistent with embodiments of the disclosure.

FIG. 6 schematically shows a change in a voltage of a battery after an addition of brine consistent with embodiments of the disclosure.

FIG. 7 is a schematic structural diagram of an example battery control system consistent with embodiments of the disclosure.

FIG. 8 is a schematic structural diagram of an example battery consistent with embodiments of the disclosure.

### DETAILED DESCRIPTION OF THE EMBODIMENTS

In order to provide a clearer illustration of purposes, technical solutions, and advantages of disclosed embodiments, example embodiments will be described with reference to the accompanying drawings. It will be appreciated that the described embodiments are some rather than all of the embodiments of the present disclosure. Other embodiments conceived by those having ordinary skills in the art on the basis of the described embodiments without inventive efforts should fall within the scope of the present disclosure.

Unless otherwise defined, all the technical and scientific terms used herein have the same or similar meanings as generally understood by one of ordinary skill in the art. As described herein, the terms used in the specification of the present disclosure are intended to describe exemplary embodiments, instead of limiting the present disclosure. The term “and/or” used herein includes any suitable combination of one or more related items listed.

Example embodiments will be described with reference to the accompanying drawings. In the situation where the technical solutions described in the embodiments are not conflicting, they can be combined.

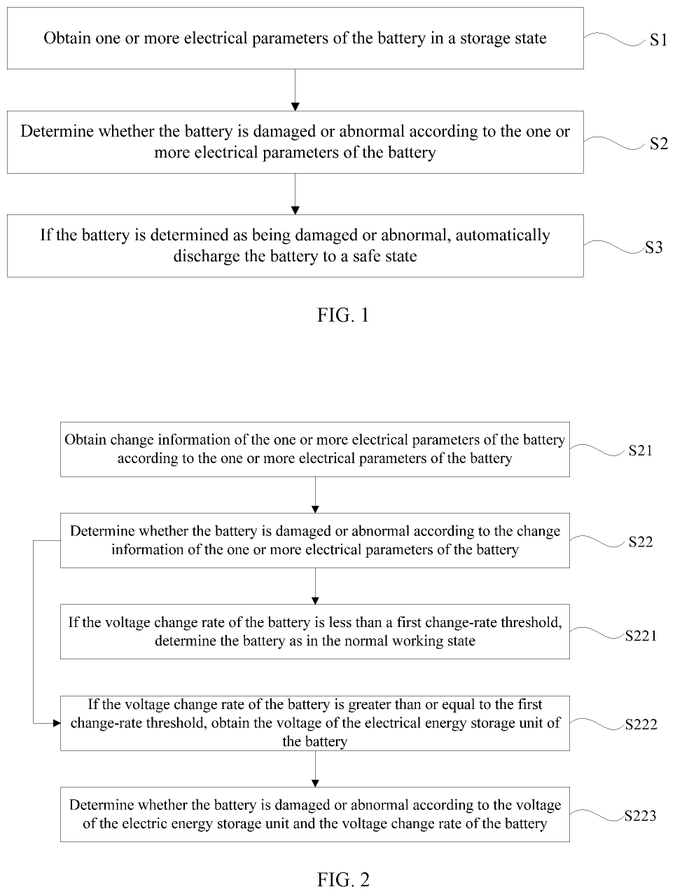

FIG. 1 is a schematic flow chart of an example battery control method consistent with the disclosure. The control method can be used for detecting a working state of a battery, and timely adjusting a working mode of the battery according to the working state of the battery to ensure a safety and reliability operation of the battery.

As shown in FIG. 1, at S1, one or more electrical parameters of the battery in a storage state are obtained. The battery generally has two working modes, i.e., a working state and the storage state. The working state of the battery can include a state when the battery is supplying power to an electronic device, and a state when the battery is being charged. The storage state of the battery refers to a state in which the battery is not supplying power to the electronic device or being charged by another power source. The storage state can be also referred to as an idle state of the battery. The one or more electrical parameters of the battery may include at least one of a voltage of the battery, a voltage of an electrical energy storage unit of the battery, a state of charge (SoC) of the electrical energy storage unit of the battery, a SoC of the battery, a self-discharge current, or the like. The electrical energy storage unit may refer to a battery cell in practical applications. Thus, the voltage of the electrical energy storage unit of the battery can include a voltage of the battery cell, and the SoC of the electrical energy storage unit of the battery can include the SoC of the battery cell. Different electrical parameters of the battery can be obtained using different methods. For example, when the one or more electrical parameters of the battery include the voltage of the battery, the voltage of the battery can be directly collected by a voltage collecting device, such as a voltage sensor or a voltage collecting circuit. When the one or more electrical parameters of the battery include the self-discharge current of the battery, the self-discharge current of the battery can be calculated indirectly from the voltage of the battery and a voltage characteristic curve of the battery. In some embodiments, the battery may include a plurality of electrical energy storage units. When the one or more electrical parameters of the battery include the voltages of the plurality of electrical energy storage units, an average voltage of the plurality of electrical energy storage units can be obtained according to the voltage of the battery and the number of the plurality of electrical energy storage units in the battery or directly collected by a voltage collecting device, such as a voltage sensor and a voltage collecting circuit of each electrical energy storage unit in the battery. Those skilled in the art may also use other methods to obtain the one or more electrical parameters of the battery, which are not limited herein.

At S2, whether the battery is damaged or abnormal is determined according to the one or more electrical parameters of the battery. After obtaining the one or more electrical parameters of the battery, the one or more electrical parameters of the battery can be analyzed, and the battery can be determined as being damaged or abnormal according to a preset analysis rule. For example, when the obtained one or more electrical parameters of the battery include a voltage change rate of the electrical energy storage unit of the battery, if the voltage change rate of the electrical energy storage unit is greater than or equal to a preset voltage change rate threshold, the battery may be determined as being damaged or abnormal according to the preset analysis rule. When the voltage change rate of the battery storage unit is less than the preset voltage change rate threshold, the battery may be determined as in a normal working state according to the preset analysis rule. In some embodiments, the battery may include the plurality of electrical energy storage units. If an average voltage change rate or a maximum voltage change rate of the plurality of electrical energy storage units is greater than or equal to the preset voltage change rate threshold, the battery may be determined as being damaged or abnormal according to the preset analysis rule, and when the average voltage change rate or the maximum voltage change rate of the plurality of battery storage units is less than the preset voltage change rate threshold, the battery may be determined as in the normal working state according to the preset analysis rule.

As another example, when the voltage of the electrical energy storage unit is greater than or equal to a voltage threshold, another electrical parameter may be obtained according to the analysis rule preset based on the voltage of the electrical energy storage unit, and whether the battery is damaged or abnormal can be further determined according to the another electrical parameter. In some embodiments, the battery may include the plurality of electrical energy storage units. If the average voltage or a maximum voltage of the plurality of the electrical energy storage units is greater than or equal to the voltage threshold, whether the battery is damaged or abnormal can be further determined according to the another electrical parameter.

Therefore, it can be appreciated that different analysis processes can be performed on different electrical parameters of the battery. No matter what electrical parameters of the battery and the corresponding analysis processes are used, whether the battery is damaged or abnormal can be determined according to an analysis result.

At S3, if the battery is determined as being damaged or abnormal, the battery is automatically discharged to a safe state. The safe state may include at least one of a state when the SoC of the battery is less than a preset SoC, a state when the voltage of the battery is less than a preset voltage, or the like. The preset SoC and the preset voltage can be preset according to specific design requirements. For example, the preset SoC can be set as 0, i.e., the charge of the battery can be completely discharged. As another example, the preset voltage can be set as 3V, 3.2V, or the like. That is, during an automatic discharge process, when the voltage of the battery is less than 3V or less than 3.2V, the automatic discharge process of the battery can be stopped, or when the voltage of the electrical energy storage unit of the battery is less than 3V or less than 3.2V, the automatic discharge process of the battery can be stopped. Other values of the preset SoC or the preset voltage can be used by those skilled in the art as long as the battery can be automatically discharged to the safe state.

Consistent with the disclosure, the battery control method can determine the one or more electrical parameters of the battery and determine whether the battery is damaged or abnormal according to the one or more electrical parameters of the battery. When the battery is determined as being damaged or abnormal, the battery can be immediately controlled to perform the automatic discharge process until the safe state is obtained. As such, problems in the conventional technologies that the battery having corrosion damage or being abnormal is liable to cause a fire and damage a mobile platform or a smart terminal, thereby posing a threat to a personal safety of a user or causing a large economic loss to the user, can be effectively overcome. A safe and reliable work of the battery can be ensured, a practicability of the control method can be improved, and a promotion and application of the market can be facilitated.

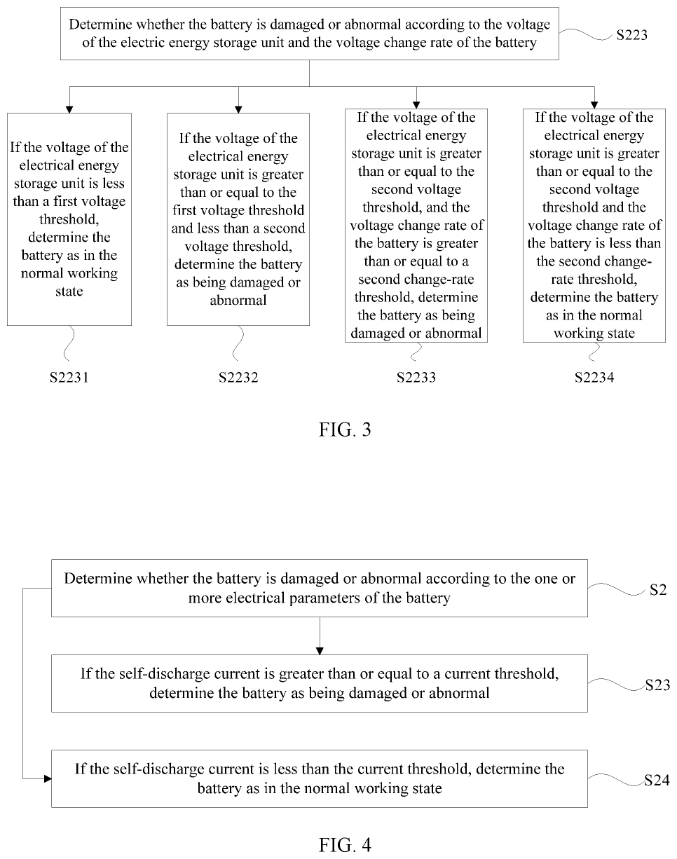

FIG. 2 is a schematic flow chart of determining whether the battery is damaged or abnormal according to the one or more electrical parameters consistent with the disclosure. FIG. 3 is a schematic flow chart of determining whether the battery is damaged or abnormal according to the voltage of the electrical energy storage unit and the voltage change rate of the battery consistent with the disclosure. It can be appreciated that the methods for determining whether the battery is damaged or abnormal according to the one or more electrical parameters of the battery are not limited herein, and those skilled in the art may use other methods according to specific design requirements.

As shown in FIG. 2, at S21, change information of the one or more electrical parameters of the battery is obtained according to the one or more electrical parameters of the battery. The change information of the one or more electrical parameters of the battery may include at least one of the voltage change rate of the battery, the voltage change rate of the electrical energy storage unit, a SoC change rate of the battery, a SoC difference of the battery, a voltage difference of the battery, a voltage difference among the plurality of the electrical energy storage units, or the like. In order to further improve the accuracy and reliability of obtaining the change information of the one or more electrical parameters, when the one or more electrical parameters of the battery are obtained, the electrical parameters of the battery may be collected in real time or at a preset collection period. After the one or more electrical parameters of the battery are obtained, the change information of the one or more electrical parameters can be obtained according to the one or more electrical parameters of the battery. For example, the one or more electrical parameters of the battery collected at a first moment can include the voltage of the battery or the voltage of the electrical energy storage unit, and the one or more electrical parameters of the battery collected at a second moment can also include the voltage of the battery or the voltage of the electrical energy storage unit. Thus, the voltage change rate of the battery or the voltage change rate of the energy storage unit can be obtained according to the data collected at the second moment and the first moment. Similarly, the change information of other electrical parameters of battery can be obtained according to the method described above. Those skilled in the art may also use other methods to obtain the change information of the one or more electrical parameters. For example, when the change information of the one or more electric parameters include the voltage change rate of the battery or the voltage change rate of the electrical energy storage unit, the voltage change rate of the battery or the voltage change rate of the electrical energy storage unit can be directly collected by, for example, a voltage change rate detector or a voltage change detection circuit.

At S22, whether the battery is damaged or abnormal is determined according to the change information of the one or more electrical parameters of the battery. After the change information of the one or more electrical parameters of the battery is obtained, and when the change information of the one or more electrical parameters of the battery includes the voltage change rate of the battery, whether the battery is damaged or abnormal may be determined according to the change information of the one or more electrical parameters and/or the electrical parameters of the battery.

In some embodiments, at S221, if the voltage change rate of the battery is less than a first change-rate threshold, the battery is determined as in the normal working state. The first change-rate threshold can be preset according to different models of batteries and specific design requirements. The first change-rate threshold can be an upper limit value of the voltage change rate of the battery in the normal working state. For example, the first change-rate threshold can be set as 3 mV/h, 5 mV/h, 6 mV/h, or the like. When the voltage change rate of the battery is analyzed and the analysis result is that the voltage change rate of the battery is less than the first change-rate threshold, the battery can be determined as in the normal working state. That is, the battery does not have any damage or abnormality.

When the analysis result is that the voltage change rate of the battery is greater than or equal to the first change-rate threshold, it indicates that the battery may be damaged or abnormal. In order to ensure an accuracy of the battery control, the one or more electrical parameters of the battery can further include the voltage of the electrical energy storage unit of the battery, and the change information of the one or more electrical parameters of the battery can include the voltage change rate of the battery. Determining whether the battery is damaged or abnormal according to the change information of the one or more electrical parameters of the battery can include the following processes.

In some embodiments, at S222, if the voltage change rate of the battery is greater than or equal to the first change-rate threshold, the voltage of the electrical energy storage unit of the battery is obtained. Since the analysis result is that the voltage change rate of the battery is greater than or equal to the first change-rate threshold, it indicates that the battery may be damaged or abnormal. In order to ensure an accurate and reliable battery control, the voltage of the electrical energy storage unit of the battery (e.g., the voltage of the battery cell) can be obtained, and whether the battery is damaged or abnormal can be determined by further analyzing the voltage of the battery cell. Determining whether the battery is damaged or abnormal according to the voltage of the electrical energy storage unit and the voltage change rate of the battery can include the following processes.

At S223, whether the battery is damaged or abnormal is determined according to the voltage of the electrical energy storage unit and the voltage change rate of the battery. After the voltage of the electrical energy storage unit is obtained, whether the battery is damaged or abnormal may be further determined according to the voltage of the electrical energy storage unit and the voltage change rate of the battery. In some embodiments, determining whether the battery is damaged or abnormal according to the voltage of the electrical energy storage unit and the voltage change rate of the battery can include the following processes.

At S2231, if the voltage of the electrical energy storage unit is less than a first voltage threshold, the battery is determined as in the normal working state. The first voltage threshold can be preset according to different models of batteries and specific design requirements. The first voltage threshold can be an upper limit value of the voltage of the electrical energy storage unit of the battery in the normal working state. For example, the first voltage threshold can be set as 3720 mV, 3920 mV, 3520 mV/h, or the like. When the voltage of the electrical energy storage unit is analyzed, and the analysis result is that the voltage of the electrical energy storage unit is less than the first voltage threshold, the battery can be determined as in the normal working state. That is, the battery does not have any damage or abnormality.

At S2232, if the voltage of the electrical energy storage unit is greater than or equal to the first voltage threshold and less than a second voltage threshold, the battery is determined as being damaged or abnormal. The second voltage threshold can be preset according to different models of batteries and specific design requirements, as long as the second voltage threshold is great than the first voltage threshold. When the analysis result is that the voltage of the electrical energy storage unit is greater than or equal to the first voltage threshold and less than the second voltage threshold, and the voltage change rate of the battery is greater than or equal to the first change-rate threshold, the battery can be determined as being damaged or abnormal.

At S2233, if the voltage of the electrical energy storage unit is greater than or equal to the second voltage threshold, and the voltage change rate of the battery is greater than or equal to a second change-rate threshold, the battery is determined as being damaged or abnormal. The second change-rate threshold can be preset according to different models of batteries and specific design requirements, as the second change-rate threshold is great than the first change-rate threshold. When the analysis result is that the voltage of the electrical energy storage unit is greater than or equal to the second voltage threshold, the battery is likely to be damaged or abnormal. In order to ensure the accuracy and reliability of the analysis, it is necessary to analyze and process the voltage change rate of the battery. Based on the analysis result described above, if the voltage change rate of the battery is greater than or equal to the second change-rate threshold, the battery can be determined as being damaged or abnormal.

At S2234, if the voltage of the electrical energy storage unit is greater than or equal to the second voltage threshold and the voltage change rate of the battery is less than the second change-rate threshold, the battery is determined as in the normal working state. When the analysis result is that the voltage of the electrical energy storage unit is greater than or equal to the second voltage threshold, the battery is likely to be damaged or abnormal. In order to ensure the accuracy and reliability of the analysis, it is necessary to analyze and process the voltage change rate of the battery. Based on the analysis result described above, if the voltage change rate of the battery is less than the second change-rate threshold, the battery can be determined as in the normal working state.

In order to better understand the analysis processes of the embodiments described above, take the first voltage threshold of 3720 mV, the second voltage threshold of 3920 mV, the first change-rate threshold of 5 mV/h, and the second change-rate threshold of 10 mV/h, as an example. The analysis result and the corresponding analysis process are shown in the Table 1.

TABLE 1
Analysis result and analysis process of
determining whether the battery is damaged or
abnormal according to the voltage of the electrical energy
storage unit and the voltage change rate of the battery.

| Voltage of the | voltage change | |
|---|---|---|
| electrical energy | rate of the | |
| storage unit/U | battery/P | State of the battery |
| U < 3720 mV | | Normal working state |
| 3720 mV ≤ U < 3920 mV | P < 5 mV/h | Normal working state |
| 3720 mV ≤ U < 3920 mV | 5 mV/h ≤ P | Damaged or abnormal |
| 3920 mV ≤ U | 10 mV/h ≤ P | Damaged or abnormal |
| 3920 mV ≤ U | P < 10 mV/h | Normal working state |

After the battery is determined as being damaged or abnormal, the battery can be controlled to self-discharge, and the battery can be discharged to the SoC of 0 or a cut-off voltage (e.g., 3V, 2.8V, or the like). Furthermore, any charging or discharging operation of the battery can be prohibited, and a battery damage warning can be sent to the user to remind the user to replace the battery in time or adopt other maintenance strategies.

Consistent with the disclosure, the voltage of the electrical energy storage unit and the voltage change rate of the battery can be obtained, and the battery can be determined as being damaged or abnormal by the voltage of the electrical energy storage unit and/or the voltage change rate of the battery. As such, not only whether the battery is damaged or abnormal can be determined according to the electrical parameters of the battery, but also an accurate and reliable determination of the battery state can be effectively ensured, thereby improving the stability and reliability of the control method.

FIG. 4 is another schematic flow chart of determining whether the battery is damaged or abnormal according to the one or more electrical parameters of the battery consistent with the disclosure. As shown in FIG. 4, other than the methods of determining whether the battery is damaged or abnormal according to the voltage of the electrical energy storage unit and the voltage change rate of the battery, the one or more electrical parameters of the battery can include the self-discharge current. Determining whether the battery is damaged or abnormally according to the one or more electrical parameters of the battery can include determining whether the battery is damaged or abnormal according to the self-discharge current of the battery.

At S23, if the self-discharge current is greater than or equal to a current threshold, the battery is determined as being damaged or abnormal. After the self-discharge current of the battery is obtained, the self-discharge current can be analyzed. For example, the self-discharge current can be compared with the current threshold. The current threshold can be preset according to different models of batteries and specific design requirements. Therefore, when the analysis result is that the self-discharge current is greater than or equal to the current threshold, the battery can be determined as being damaged or abnormal.

At S24, if the self-discharge current is less than the current threshold, the battery is determined as in the normal working state. When the self-discharge current is compared with the current threshold and the comparison result is that the self-discharge current is less than the current threshold, the battery is determined as in the normal working state.

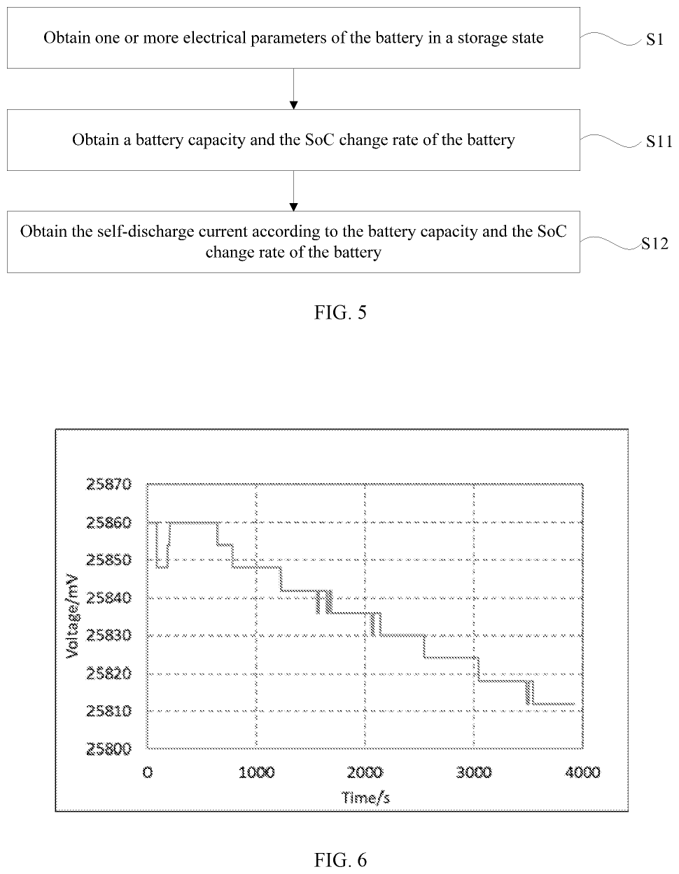

FIG. 5 is a schematic flow chart of obtaining the one or more electrical parameters of the battery in the storage state consistent with the disclosure. As shown in FIG. 5, when the one or more electrical parameters of the battery include the self-discharge current, obtaining the one or more electrical parameters of the battery in the storage state can include the following processes.

At S11, a battery capacity and the SoC change rate of the battery are obtained. The battery capacity can be obtained from a supplier of the battery cell or calculated using a capacity estimation algorithm. The SoC change rate of the battery can be obtained by first obtaining the voltage of the battery, and then determining the SoC of the battery by calculating the voltage of the battery, and finally obtaining the SoC change state. Those skilled in the art can also use other methods, as long as the battery capacity and the SoC change rate of the battery can be ensured to be accurately obtained, and detailed description thereof is omitted herein.

At S12, the self-discharge current is obtained according to the battery capacity and the SoC change rate of the battery. The self-discharge current can be proportional to a product of the SoC change rate of the battery and the battery capacity. For example, the self-discharge current can be obtained according to the formula

$$I = \frac{dSOC}{dt} * Cap ,$$

where I is the self-discharge current,

$$\frac{dSOC}{dt}$$

is the SoC change rate of the battery, and Cap is the battery capacity.

Consistent with the disclosure, the self-discharge current can be obtained according to the method described above, and whether the battery is damaged or abnormal can be determined by analyzing the self-discharge current. As such, not only an accuracy and reliability of obtaining the self-discharge current can be ensured, but also the implementation of the battery control method can be expanded. The specific working state of the battery can be accurately determined, thereby improving the stability and reliability of the control method.

In specific applications, different battery models can have different current thresholds. In order to accurately obtain the current threshold, take a fresh battery 1C charged to the SOC of 100% and left standing for 12 hours as an example. The battery is tested in different possible working environments of the battery (e.g., room temperature, high temperature, and critical environment for corrosion damage to the battery) to explain the methods for obtaining the current threshold.

(1) Room Temperature Self-Discharge Test.

The fresh battery 1C is charged to the SOC of 100%, left standing for 12 hours, and stored at the room temperature (i.e., 25° C.). The battery is waken up every 1 hour to read the voltage of the battery cell (e.g., the voltage the electrical energy storage unit described above) and the voltage of the battery. The corresponding voltage change rate, the SOC change rate, and the self-discharge current can be calculated according to the voltage of the battery and the voltage of the battery cell. Table 2 shows the test results at the room temperature.

TABLE 2
Self-discharge test results at room temperature

| | | | | | | | Sigma/ |
|---|---|---|---|---|---|---|---|
| | Battery serial number | | | | | | Standard |
| | 1 | 2 | 3 | 4 | 5 | mean | deviation |
| Average voltage | 0.07 | 0.15 | 0.09 | 0.08 | 0.12 | 0.10 | 0.03 |
| change rate of the | | | | | | | |
| battery cell mV/h | | | | | | | |
| Average SoC | 0.006 | 0.013 | 0.008 | 0.007 | 0.01 | 0.009 | 0.003 |
| change | | | | | | | |
| rate of the battery | | | | | | | |
| cell %/h | | | | | | | |
| Average self- | 0.24 | 0.51 | 0.33 | 0.30 | 0.41 | 0.36 | 0.10 |
| discharge | | | | | | | |
| current mA | | | | | | | |
| Maximum voltage | 0.07 | 0.18 | 0.11 | 0.11 | 0.14 | 0.12 | 0.04 |
| change rate of the | | | | | | | |
| battery cell mV/h | | | | | | | |
| Maximum SoC | 0.006 | 0.016 | 0.009 | 0.009 | 0.01 | 0.01 | 0.004 |
| change rate of the | | | | | | | |
| battery cell %/h | | | | | | | |
| Maximum self- | 0.24 | 0.65 | 0.40 | 0.38 | 0.49 | 0.43 | 0.15 |
| discharge | | | | | | | |
| current mA | | | | | | | |

The reason that the battery needs to be left standing for 12 hours when obtaining data in Table 2 is due to characteristics of the battery. For example, when the battery is at a full voltage, the voltage of the battery is generally unstable. Therefore, the data collected at the full voltage can be relatively inaccurate. As such, data information can be more accurately collected after the battery is left standing for 12 hours.

According to the data shown in Table 2, and assume that the self-discharge rate conforms to the normal distribution, a probability of the average self-discharge current at 25° C. to be greater than the mean of the average self-discharge current plus six times of the sigma of the average self-discharge current (i.e., 0.96 mA) is less than 0.0015%. An upper limit of the maximum self-discharge current at 25° C. equals to the mean of the maximum self-discharge current plus six times of the sigma of the maximum self-discharge current, i.e., 1.33 mA.

(2) High Temperature Self-Discharge Test.

The fresh battery 1C is charged to the SOC of 100%, left standing for 12 hours, and stored at the high temperature (i.e., 45° C.). The battery is waken up every 1 hour to read the voltage of the battery cell and the voltage of the battery. The corresponding voltage change rate, the SOC change rate, and the self-discharge current can be calculated according to the voltage of the battery and the voltage of the battery cell. Table 3 shows the test results at the high temperature.

TABLE 3
Self-discharge test results at high temperature

| | Battery serial number | | | | | | | |
|---|---|---|---|---|---|---|---|---|
| | 1 | 2 | 3 | 4 | 5 | 6 | mean | sigma |
| Average voltage change rate | 0.38 | 0.25 | 0.31 | 0.44 | 0.44 | 0.50 | 0.39 | 0.10 |
| of the battery cell mV/h | | | | | | | | |
| Average SoC change rate of | 0.03 | 0.02 | 0.03 | 0.04 | 0.04 | 0.04 | 0.033 | 0.008 |
| the battery cell %/h | | | | | | | | |
| Average self-discharge | 1.37 | 0.91 | 1.09 | 1.55 | 1.58 | 1.81 | 1.39 | 0.37 |
| current mA | | | | | | | | |
| Maximum voltage change | 0.39 | 0.31 | 0.35 | 0.46 | 0.49 | 0.53 | 0.43 | 0.09 |
| rate of the battery cell mV/h | | | | | | | | |
| Maximum SoC change rate | 0.03 | 0.03 | 0.03 | 0.039 | 0.04 | 0.04 | 0.04 | 0.008 |
| of the battery cell %/h | | | | | | | | |
| Maximum self-discharge | 1.41 | 1.09 | 1.22 | 1.65 | 1.78 | 1.93 | 1.53 | 0.36 |
| current mA | | | | | | | | |

According to the data shown in Table 3, a probability of the average self-discharge current at 45° C. to be greater than the mean of the average self-discharge current plus six times of the sigma of the average self-discharge current (i.e., 3.63 mA) is less than 0.0015%. An upper limit of the maximum self-discharge current at 45° C. equals to the mean of the maximum self-discharge current plus six times of the sigma of the maximum self-discharge current, i.e., 3.68 mA.

The self-discharge rate at 45° C. is much higher than at 25° C., and a higher storage temperature corresponds to a higher self-discharge rate. In order to avoid misjudgment, the self-discharge current corresponding to a corrosion short-circuit criterion can be higher than 3.68 mA.

(3) Test of a Corrosion-Damaged Battery.

The fresh battery 1C is charged to the SOC of 100% and left standing for 12 hours. Brine of 2% concentration is added to a battery circuit board, and the board experiences a severe corrosion reaction to accelerate a corrosion of the board. The voltage of the battery and the voltage of the battery cell are measured every 1 second. FIG. 6 schematically shows a change in the voltage of the battery after an addition of brine consistent with the disclosure. After the Nth dropwise addition of brine, the change in the voltage of the battery is shown in FIG. 6.

In addition to change data of the voltage of the battery shown in FIG. 6, an open circuit voltage (OCV) curve of the battery can be also detected. According to the voltage of the battery and the OCV curve, data in Table 4 can be obtained using a current calculation formula

$$I = \frac{dSOC}{dt} * Cap .$$

TABLE 4
Self-discharge test results of the corrosion-damaged battery

| Voltage change rate of | SoC | | |
|---|---|---|---|
| the battery cell | change rate | Capacity | current |
| 4.57 mV/h | 0.39%/h | 4.29 Ah | 16.58 mA |

As shown in Table 4, a maximum current is 16.58 mA in a case of corrosion damage. A current consumption of the board can be obtained and deducted from the maximum current, and hence a maximum corrosion current can be obtained as 12.75 mA. The maximum corrosion current can be used as the current threshold, such that the accuracy of obtaining the current threshold can be ensured.

The current consumption of the board can be obtained by the following methods. When each battery cell in the battery is scanned to obtain the voltage of the battery cell, a largest value of a power consumption of the board can be achieved and when the entire battery is scanned to obtain the voltage of the battery, a smallest value of the power consumption of the board can be achieved. The smallest value can be regarded as zero. Thus, a voltage consumption of the board can be obtained when each battery cell in the battery is scanned. The current consumption of the board can be obtained according to a consumption resistance value of the board and the consumption voltage of the board. In some embodiments, the current consumption of the board can be directly measured, as long as an accuracy of the current consumption of the board can be ensured, and detailed description is thereof omitted herein.

In the test of the corrosion-damaged battery, if the brine is continuously added to the battery circuit board, the board will continue to burn at high temperatures. A corrosion state of the battery in the test in Table 4 is defined as a critical corrosion combustion state before a combustion of the battery occurs. For example, after the N+1th dropwise addition of brine, the battery is burned, and hence a corresponding corrosion degree of the board after the Nth dropwise addition of brine can be measured as the critical corrosion combustion state.

In a retest process of the corrosion-damaged battery, a corrosion current gradually increases as a corrosion level increases. After the critical corrosion combustion state is reached, if the brine is added again, the battery can burn. Since the corrosion is related to a layout of the board, the entire battery may be corroded and short-circuited, or one or some of the battery cells may be corroded and short-circuited.

After implementing the test processes described above, different current thresholds for different battery models can be accurately obtained. After the current threshold is obtained, the current threshold can be used to perform a safety detection on the battery. The safety detection can be performed as follows. The fresh battery 1C is charged to the SOC of 100% and left standing for 12 hours. The brine is added to the board to accelerate the corrosion of the board and a thermal imager is used to observe temperatures of the board. When the brine is dripped, severe corrosion reaction occurs and the temperature at a short-circuit point near a connector of the battery is the highest, and the temperature rises rapidly to 70-80° C. The detected temperature does not exceed 80° C., which is the temperature at which the battery can be in the normal working state. After the severe corrosion reaction is over, the short-circuit temperature is always maintained at around 30° C.

As the self-discharge progress proceeds, the battery cell can undergo an inflation failure and no longer provide a voltage for corrosion, such that the corrosion can be difficult to sustain, and combustion does not occur. The phenomenon described above indicates that the battery is self-discharged, thereby avoiding the corrosion of the battery and ensuring the safety and reliability of the battery.

In some embodiments, the battery control method can include the following processes.

At 1, whether the battery is in a stable state is determined.

At 1-1, a battery state is determined from a start time of a storage time of the battery (i.e., TimeCount=0).

At 1-2, whether the self-discharge current is less than a preset value of the self-discharge current I1 is determined. When the battery is in a standing state, the self-discharge process can be generally proceeded, and hence there is a certain self-discharge current in the standing state. A value of I1 can be small.

At 1-3, if the self-discharge current is greater than or equal to I1, the battery is determined as in an unstable state, and the proceeding returns to the process at 1-1; if the self-discharge current is less than I1, the battery continues to be stored according to the storage time (e.g., TimeCount++).

At 1-4, as the storage time continues to increase, whether the storage time (i.e., TimeCount) is greater than or equal to a preset value of the storage time T1 is determined. If the storage time is greater than or equal to T1, the battery can be determined as in the stable state, otherwise, in the unstable state. For example, the preset value of the storage time T1 can be set as 12 hours as in Tables 2 to 4.

At 2, a test and control process is proceeded on the battery.

At 2-1, when the TimeCount is less than the preset value of the storage time T1, the battery is determined as not in the stable state at the moment, then the proceeding returns to the process at S1-2; when the TimeCount is greater than or equal to the preset value of the storage time T1, the battery is determined as in the stable state at the moment, an initial voltage V0 of the battery is recorded, and time information for collecting the initial voltage of the battery V0 is also recorded.

At 2-2, whether the self-discharge current of the battery is less than the preset value of the self-discharge current I1 is further determined.

At 2-3, if the self-discharge current is greater than or equal to I1, the battery is determined as not in the storage state, and the proceeding returns to the process at S1-1; if the self-discharge current is less than I1, the battery continues to be stored according to the storage time (i.e., TimeCount++).

At 2-4, the voltage of battery is collected according to a preset collection time interval. For example, whether the TimeCount is greater than or equal to a preset value T2. The preset value T2 is the preset collection time interval, for example, may be 1 hour, 2 hours, or the like.

At 2-5, when TimeCount is less than the preset value T2, the collection time interval is determined to be not arrived at the moment, and the proceeding returns to the process at 2-2; when the TimeCount is greater than or equal to the preset value T2, the voltage V1 of the battery is recorded, and the voltage change rate is calculated according to a formula

$$\frac{dV}{dt} = \frac{( V 1 - V 0 )}{T 2} ,$$

and the collection time interval is reset (i.e., TimeCount=0).

At 2-6, whether the voltage of the battery V1 is greater than or equal to a first calibration value of the voltage V00 is determined. The first calibration value of the voltage V00 can be preset as, for example, 3920 mV in Table 1.

At 2-7, if V1 is greater than or equal to the first calibration value of the voltage V00, whether the voltage change rate dV/dt is greater than or equal to a first calibration value of the voltage change rate dV/dt1 is determined. The first calibration value of the voltage change rate dV/dt1 can be preset as, for example, 10 mV/h in Table 1.

At 2-8, if the voltage change rate dV/dt is greater than or equal to the first calibration value of the voltage change rate dV/dt1, the battery is determined as being damaged or abnormal. A self-discharge mode of the battery can be turned on, the charging and discharging operation of the battery can be prohibited, and an alarm prompt message can be sent to the user. If the voltage change rate dV/dt is less than the first calibration value of the voltage change rate dV/dt1, the proceeding returns to 2-2.

At 2-9, if V1 is less than the first calibration value of the voltage V00, whether the V1 is greater than or equal to a second calibration value of the voltage V01 is determined. The second calibration value of the voltage V01 can be preset as, for example, 3720 mV in Table 1.

At 2-10, if V1 is less than the second calibration value of the voltage V01, the detection and control process on the battery is ended; if V1 is greater than or equal to the second calibration value of the voltage V01, whether the voltage change rate dV/dt is greater than or equal to a second calibration value of the voltage change rate dV/dt2 is further determined. The second calibration value of the voltage change rate dV/dt2 can be preset as, for example, 5 mV/h in Table 1. If the voltage change rate dV/dt is greater than or equal to the second calibration value of the voltage change rate dV/dt2, the battery is determined as being damaged or abnormal. The self-discharge mode of the battery can be turned on, the charging and discharging operation of the battery can be prohibited, and the alarm prompt message can be sent to the user. If the voltage change rate dV/dt is less than the second calibration value of the voltage change rate dV/dt2, the proceeding returns to 2-2.

A damaged or abnormal battery can eliminate safety hazards through self-discharge. A cut-off condition of the discharge is not limited to a full discharge (i.e., the SoC of 0). A safety upper limit threshold of the voltage or the SOC of the battery can be determined according to experiments, and the battery can be discharged to be below the safe upper limit threshold. The damaged battery can also eliminate the safety hazards using low temperatures, such that the maximum temperature of the battery can be below an ignition point, thereby avoiding the corrosion. In some embodiments, the self-discharge process and the low temperatures can be combined to eliminate the safety hazards. Through performing the detection and control process on the battery, the safety hazards in the storage or use of the battery can be effectively eliminated, the harm to the personal or customer properties can be avoided, the practicality of the battery control method of the battery can be improved, and the promotion and application of the market can be facilitated.

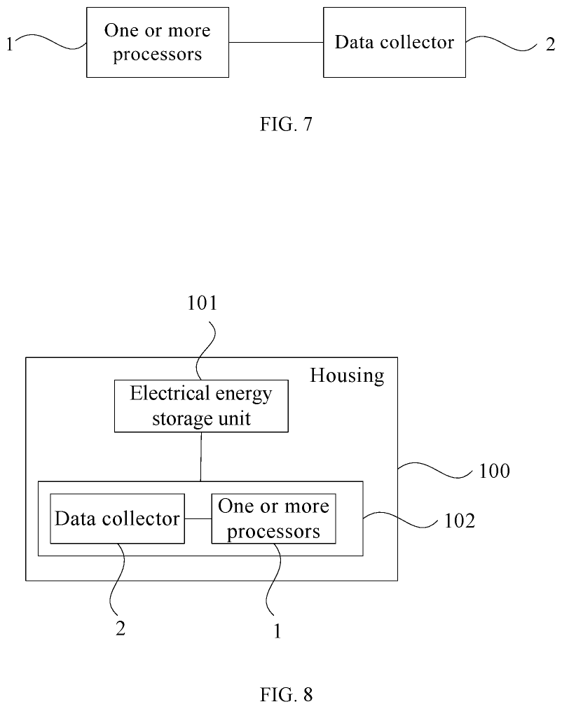

FIG. 7 is a structural schematic diagram of an example battery control system consistent with the disclosure. The battery control system can be configured to detect and control the working state of the battery. As shown in FIG. 7, the control system includes a data collector 2 and one or more processors 1. The data collector 2 is communicatively coupled to the one or more processors 1. The one or more processors 1 can work individually or collectively. In some embodiments, the data collector 2 can be integrated into the one or more processors 1. If the function of the data collector 2 is integrated in the one or more processors 1, the control system can include only the one or more processors 1.

The data collector 2 can be configured to collect the one or more electrical parameters of the battery in the storage state, and send the one or more electrical parameters to the one or more processors 1. Different electrical parameters may correspond to different data collectors 2. For example, the data collector 2 may be a voltage sensor, a current sensor, or the like.

The one or more processes 1 can be configured to obtain the one or more electrical parameters of the battery in the storage state, determine whether the battery is damaged or abnormal according to the one or more electrical parameters of the battery, and if the battery is determined as being damaged or abnormal, automatically discharge the battery to the safe state.

The one or more electrical parameters of the battery may include at least one of the voltage of the battery, the voltage of the electrical energy storage unit of the battery, the SoC of the electrical energy storage unit of the battery, the SoC of the battery, the self-discharge current, or the like. The safe state may include at least one of the state when the SoC of the battery is less than the preset SoC, the state when the voltage of the battery is less than the preset voltage, or the like.

In some embodiments, when determining whether the battery is damaged or abnormal according to the one or more electrical parameters of the battery, the one or more processors 1 can be configured to obtain the change information of the one or more electrical parameters of the battery according to the one or more electrical parameters of the battery, and determine whether the battery is damaged or abnormal according to the change information of the one or more electrical parameters of the battery.

The change information of the one or more electrical parameters of the battery may include at least one of the voltage change rate of the battery, the voltage change rate of the electrical energy storage unit, the SoC change rate of the battery, the SoC difference of the battery, the voltage difference of the battery, the voltage difference among the plurality of the electrical energy storage units, or the like.

When the change information of the one or more electrical parameters of the battery includes the voltage change rate of the battery, and whether the battery is damaged or abnormal is determined according to the change information of the one or more electrical parameters of the battery, the one or more processors 1 can be configured to determine the battery as in the normal working state in response to the voltage change rate of the battery is less than the first change-rate threshold.

When the one or more electrical parameters of the battery include the voltage of the electrical energy storage unit and the change information of the one or more electrical parameters of the battery includes the voltage change rate of the battery, and whether the battery is damaged or abnormal is determined according to the change information of the one or more electrical parameters of the battery, the one or more processors 1 can be configured to obtain the voltage of the electrical energy storage unit of the battery, in response to the voltage change rate of the battery is greater than or equal to the first change-rate threshold, and determine whether the battery is damaged or abnormal according to the voltage of the electrical energy storage unit and the voltage change rate of the battery.

In some embodiments, when determining whether the battery is damaged or abnormal according to the voltage of the electrical energy storage unit and the voltage change rate of the battery, the one or more processors 1 can be further configured to determine the battery as in the normal working state in response to the voltage of the electrical energy storage unit is less than the first voltage threshold, or determine the battery as being damaged or abnormal in response to the voltage of the electrical energy storage unit is greater than or equal to the first voltage threshold and less than the second voltage threshold, or determine the battery as being damaged or abnormal in response to the voltage of the electrical energy storage unit is greater than or equal to the second voltage threshold and the voltage change rate of the battery is greater than or equal to the second change-rate threshold, or determine the battery as in the normal working state, in response to the voltage of the electrical energy storage unit is greater than or equal to the second voltage threshold and the voltage change rate of the battery is less than the second change-rate threshold. The second voltage threshold can be greater than the first voltage threshold and the second change-rate threshold can be greater than the first change-rate threshold.

In some embodiments, when the one or more electrical parameters of the battery include the self-discharge current, and whether the battery is damaged or abnormal is determined according to the one or more electrical parameters of the battery, the one or more processors 1 can be configured to determine the battery as being damaged or abnormal in response to the self-discharge current is greater than or equal to the current threshold, and determine the battery as in the normal working state in response to the self-discharge current is less than the current threshold.

In some embodiments, when the one or more electrical parameters of the battery include the self-discharge current, and when obtaining the one or more electrical parameters of the battery in the storage state, the one or more processors 1 can be configured to obtain the battery capacity and the SoC change rate of the battery, and obtain the self-discharge current according to the battery capacity and the SoC change rate of the battery.

In some embodiments, when obtaining the self-discharge current according to the battery capacity and the SoC change rate of the battery, the one or more processors 1 can be configured to obtain the self-discharge current as being proportional to the product of the SoC change rate of the battery and the battery capacity.

The specific principles and implementation processes of the battery control system in FIG. 7 are similar to those of the control methods shown in FIGS. 1 to 6, and detailed description thereof is omitted herein.

Consistent with the disclosure, the one or more processes 1 of the battery control system can be configured to obtain the one or more electrical parameters of the battery, determine whether the battery is damaged or abnormal according to the one or more electrical parameters of the battery, and immediately discharge the battery to the safe state in response to the battery is determined as being damaged or abnormal. As such, the problems in the conventional technologies that the battery having corrosion damage or being abnormal is liable to cause the fire and damage the mobile platform or the smart terminal, thereby posing the threat to the personal safety of the user or causing the large economic loss to the user, can be effectively overcome. The safe and reliable work of the battery can be ensured, the practicability of the control method can be improved, and the promotion and application of the market can be facilitated.

In some embodiments, an example computer readable storage medium consistent with the disclosure is provided. The computer readable storage medium can include instructions that, when executed by a computer, cause the computer to perform the battery control method consistent with the disclosure. The battery control method can include obtaining the one or more electrical parameters of the battery in the storage state, determining whether the battery is damaged or abnormal according to the one or more electrical parameters of the battery, and if the battery is determined as being damaged or abnormal, automatically discharging the battery to the safe state.

The one or more electrical parameters of the battery may include at least one of the voltage of the battery, the voltage of the electrical energy storage unit of the battery, the SoC of the electrical energy storage unit of the battery, the SoC of the battery, the self-discharge current, or the like. The safe state may include at least one of the state when the SoC of the battery is less than the preset SoC, the state when the voltage of the battery is less than the preset voltage, or the like.

In some embodiments, determining whether the battery is damaged or abnormal according to the one or more electrical parameters of the battery can include obtaining the change information of the one or more electrical parameters of the battery according to the one or more electrical parameters of the battery, and determining whether the battery is damaged or abnormal according to the change information of the one or more electrical parameters of the battery.

The change information of the one or more electrical parameters of the battery may include at least one of the voltage change rate of the battery, the voltage change rate of the electrical energy storage unit, the SoC change rate of the battery, the SoC difference of the battery, the voltage difference of the battery, the voltage difference among the plurality of the electrical energy storage units, or the like.

In some embodiments, when the change information of the one or more electrical parameters of the battery includes the voltage change rate of the battery, determining whether the battery is damaged or abnormal according to the change information of the one or more electrical parameters of the battery can include determining the battery as in the normal working state in response to the voltage change rate of the battery is less than the first change-rate threshold.

In some embodiments, when the one or more electrical parameters of the battery include the voltage of the electrical energy storage unit and the change information of the one or more electrical parameters of the battery includes the voltage change rate of the battery, determining whether the battery is damaged or abnormal according to the change information of the one or more electrical parameters of the battery can include obtaining the voltage of the electrical energy storage unit of the battery, in response to the voltage change rate of the battery is greater than or equal to the first change-rate threshold, and determining whether the battery is damaged or abnormal according to the voltage of the electrical energy storage unit and the voltage change rate of the battery.

In some embodiments, determining whether the battery is damaged or abnormal according to the voltage of the electrical energy storage unit and the voltage change rate of the battery can include determining the battery as in the normal working state in response to the voltage of the electrical energy storage unit is less than the first voltage threshold, or determining the battery as being damaged or abnormal in response to the voltage of the electrical energy storage unit is greater than or equal to the first voltage threshold and less than the second voltage threshold, or determining the battery as being damaged or abnormal in response to the voltage of the electrical energy storage unit is greater than or equal to the second voltage threshold and the voltage change rate of the battery is greater than or equal to the second change-rate threshold, or determining the battery as in the normal working state, in response to the voltage of the electrical energy storage unit is greater than or equal to the second voltage threshold and the voltage change rate of the battery is less than the second change-rate threshold. The second voltage threshold can be greater than the first voltage threshold and the second change-rate threshold can be greater than the first change-rate threshold.

In some embodiments, when the one or more electrical parameters of the battery include the self-discharge current, determining whether the battery is damaged or abnormal according to the one or more electrical parameters of the battery can include determining the battery as being damaged or abnormal in response to the self-discharge current is greater than or equal to the current threshold, and determining the battery as in the normal working state in response to the self-discharge current is less than the current threshold.

In some embodiments, when the one or more electrical parameters of the battery include the self-discharge current, obtaining the one or more electrical parameters of the battery in the storage state can include obtaining the battery capacity and the SoC change rate of the battery, and obtaining the self-discharge current according to the battery capacity and the SoC change rate of the battery. For example, obtaining the self-discharge current according to the battery capacity and the SoC change rate of the battery can include obtaining the self-discharge current as being proportional to the product of the SoC change rate of the battery and the battery capacity.

The specific principles and implementation processes of the computer readable storage medium are similar to those of the control methods shown in FIGS. 1 to 6, and detailed description thereof is omitted herein.

FIG. 8 is a structural schematic diagram of an example battery consistent with the disclosure. The battery can be configured to power other electronic devices. As shown in FIG. 8, the battery includes a housing 100, an electrical energy storage unit 101 mounted inside the housing 100, and a battery control system 102 electrically coupled to the electrical energy storage unit 101.

The electrical energy storage unit 101 can be charged or discharged by the battery control system 102. The battery control system 102 includes the data collector 2 and the one or more processors 1. The data collector 2 is communicatively coupled to the one or more processors 1. The one or more processors 1 can work individually or collectively. The data collector 2 can be configured to collect the one or more electrical parameters of the battery in the storage state, and send the one or more electrical parameters to the one or more processors 1. The one or more processes 1 can be configured to obtain the one or more electrical parameters of the battery in the storage state, determine whether the battery is damaged or abnormal according to the one or more electrical parameters of the battery, and if the battery is determined as being damaged or abnormal, automatically discharge the battery to the safe state.

The one or more electrical parameters of the battery may include at least one of the voltage of the battery, the voltage of the electrical energy storage unit of the battery, the SoC of the electrical energy storage unit of the battery, the SoC of the battery, the self-discharge current, or the like. The safe state may include at least one of the state when the SoC of the battery is less than the preset SoC, the state when the voltage of the battery is less than the preset voltage, or the like.

In some embodiments, when determining whether the battery is damaged or abnormal according to the one or more electrical parameters of the battery, the one or more processors 1 can be configured to obtain the change information of the one or more electrical parameters of the battery according to the one or more electrical parameters of the battery, and determine whether the battery is damaged or abnormal according to the change information of the one or more electrical parameters of the battery.

The change information of the one or more electrical parameters of the battery may include at least one of the voltage change rate of the battery, the voltage change rate of the electrical energy storage unit, the SoC change rate of the battery, the SoC difference of the battery, the voltage difference of the battery, the voltage difference among the plurality of the electrical energy storage units, or the like.

When the change information of the one or more electrical parameters of the battery includes the voltage change rate of the battery, and whether the battery is damaged or abnormal is determined according to the change information of the one or more electrical parameters of the battery, the one or more processors 1 can be configured to determine the battery as in the normal working state in response to the voltage change rate of the battery is less than the first change-rate threshold.

When the one or more electrical parameters of the battery include the voltage of the electrical energy storage unit and the change information of the one or more electrical parameters of the battery includes the voltage change rate of the battery, and whether the battery is damaged or abnormal is determined according to the change information of the one or more electrical parameters of the battery, the one or more processors 1 can be configured to obtain the voltage of the electrical energy storage unit of the battery, in response to the voltage change rate of the battery is greater than or equal to the first change-rate threshold, and determine whether the battery is damaged or abnormal according to the voltage of the electrical energy storage unit and the voltage change rate of the battery.

In some embodiments, when determining whether the battery is damaged or abnormal according to the voltage of the electrical energy storage unit and the voltage change rate of the battery, the one or more processors 1 can be further configured to determine the battery as in the normal working state in response to the voltage of the electrical energy storage unit is less than the first voltage threshold, or determine the battery as being damaged or abnormal in response to the voltage of the electrical energy storage unit is greater than or equal to the first voltage threshold and less than the second voltage threshold, or determine the battery as being damaged or abnormal, in response to the voltage of the electrical energy storage unit is greater than or equal to the second voltage threshold and the voltage change rate of the battery is greater than or equal to the second change-rate threshold, or determine the battery as in the normal working state, in response to the voltage of the electrical energy storage unit is greater than or equal to the second voltage threshold and the voltage change rate of the battery is less than the second change-rate threshold. The second voltage threshold can be greater than the first voltage threshold and the second change-rate threshold can be greater than the first change-rate threshold.

In some embodiments, when the one or more electrical parameters of the battery include the self-discharge current, and whether the battery is damaged or abnormal is determined according to the one or more electrical parameters of the battery, the one or more processors 1 can be configured to determine the battery as being damaged or abnormal in response to the self-discharge current is greater than or equal to the current threshold, and determine the battery as in the normal working state in response to the self-discharge current is less than the current threshold.

In some embodiments, when obtaining the one or more electrical parameters of the battery in the storage state, the one or more processors 1 can be configured to obtain the battery capacity and the SoC change rate of the battery, and obtain the self-discharge current according to the battery capacity and the SoC change rate of the battery.

The specific principles and implementation processes of the battery are similar to those of the control methods shown in FIGS. 1 to 6, and detailed description thereof is omitted herein.

Consistent with the disclosure, the battery can include the battery control system. The one or more processes 1 of the battery control system can be configured to obtain the one or more electrical parameters of the battery, determine whether the battery is damaged or abnormal according to the one or more electrical parameters of the battery, and immediately discharge the battery to the safe state in response to the battery is determined as being damaged or abnormal. As such, the problems in the conventional technologies that the battery having corrosion damage or being abnormal is liable to cause the fire and damage the mobile platform or the smart terminal, thereby posing the threat to the personal safety of the user or causing the large economic loss to the user, can be effectively overcome. The safe and reliable work of the battery can be ensured, the practicability of the control method can be improved, and the promotion and application of the market can be facilitated.

In some embodiments, an example mobile platform consistent with the disclosure is provided. The mobile platform can include a motor and the battery consistent with the disclosure providing power to the motor.

The mobile platform can include at least one of a gimbal, an electric car, or an unmanned aerial vehicle (UAV).

Consistent with the disclosure, the mobile platform can include the battery. The battery can be configured to obtain the one or more electrical parameters of the battery, determine whether the battery is damaged or abnormal according to the one or more electrical parameters of the battery, and immediately discharge the battery to the safe state in response to the battery is determined as being damaged or abnormal. As such, the problems in the conventional technologies that the battery having corrosion damage or being abnormal is liable to cause the fire and damage the mobile platform or the smart terminal, thereby posing the threat to the personal safety of the user or causing the large economic loss to the user, can be effectively overcome. The safe and reliable work of the battery can be ensured, the practicability of the control method can be improved, and the promotion and application of the market can be facilitated.

In the situation where the technical solutions and technical features described in the embodiments are not conflicting, they can be separated or combined. As long as the separated or combined embodiments does not exceed the scope of knowledge of those skilled in the art, they are intended to be within the scope of the present disclosure.

The disclosed apparatuses and methods may be implemented in other manners not described here. For example, the apparatuses described above are merely illustrative. For example, the division of units may only be a logical function division, and there may be other ways of dividing the units. For example, multiple units or components may be combined or may be integrated into another system, or some features may be ignored, or not executed. Further, the coupling or direct coupling or communication connection shown or discussed may include a direct connection or an indirect connection or communication connection through one or more interfaces, devices, or units, which may be electrical, mechanical, or in other form.

The units described as separate components may or may not be physically separate, and a component shown as a unit may or may not be a physical unit. That is, the units may be located in one place or may be distributed over a plurality of network elements. Some or all of the components may be selected according to the actual needs to achieve the object of the present disclosure.

In addition, the functional units in the various embodiments of the present disclosure may be integrated in one processing unit, or each unit may be an individual physically unit, or two or more units may be integrated in one unit. The integrated unit described above can be implemented in electronic hardware or in computer software.

The integrated unit can be implemented in the form of computer program stored in a non-transitory computer-readable storage medium, which can be sold or used as a standalone product. The technical solutions of the present disclosure, which is essential or contributes to the prior art, or all or part of the technical solutions, can be implemented in the form of the software product. The computer program can include instructions stored in a storage medium, when executed by the one or more processors 1, causing the one or more processors 1 to perform part or all of a method consistent with the disclosure, such as one of the exemplary methods described above. The storage medium can be any medium that can store program codes, for example, a USB disk, a mobile hard disk, a read-only memory (ROM), a random access memory (RAM), a magnetic disk, or an optical disk.

It is intended that the specification and examples be considered as exemplary only and not to limit the scope of the disclosure. The equivalent structure or equivalent process transformations made in the light of the present specification and the drawings, which can be directly or indirectly applied to other related technical fields, are included in the scope of the present disclosure.

It is intended that the embodiments disclosed herein are merely for illustrating the technical solutions of the present disclosure and not to limit the scope of the disclosure. Changes, modifications, alterations, and variations of the above-described embodiments may be made by those skilled in the art without departing from the scope of the disclosure. The scope of the invention can be defined by the following claims or equivalent thereof.

What is claimed is:

1. A battery comprising:
a housing;
an electrical energy storage unit mounted inside the housing; and
a battery control system electrically coupled to the electrical energy storage unit to control charge and discharge of the electrical energy storage unit, the battery control system including one or more processors configured to:
obtain one or more electrical parameters of the battery in a storage state;
determine whether the battery is damaged or abnormal according to the one or more electrical parameters of the battery; and
automatically discharge the battery to a safe state in response to determining that the battery is damaged or abnormal.

2. The battery of claim 1, wherein the battery control system further includes:
a data collector communicatively coupled to the one or more processors and configured to:
collect the one or more electrical parameters of the battery in the storage state; and
send the one or more electrical parameters to the one or more processors.

3. The battery of claim 1, wherein the one or more electrical parameters of the battery include at least one of a voltage of the battery, a voltage of the electrical energy storage unit of the battery, a state of charge (SoC) of the electrical energy storage unit of the battery, an SoC of the battery, or a self-discharge current.

4. The battery of claim 1, wherein the one or more processors are further configured to:
obtain change information of the one or more electrical parameters of the battery according to the one or more electrical parameters of the battery; and
determine whether the battery is damaged or abnormal according to the change information of the one or more electrical parameters of the battery.

5. The battery of claim 4, wherein the change information of the one or more electrical parameters of the battery includes at least one of a voltage change rate of the battery, a voltage change rate of the electrical energy storage unit, a state of charge (SoC) change rate of the battery, an SoC difference of the battery, a voltage difference of the battery, or a voltage difference between the electrical energy storage unit and another electrical energy storage unit of the battery.

6. The battery of claim 5, wherein the one or more processors are further configured to:
determine the battery as in a normal working state in response to determining that the voltage change rate of the battery is less than a change-rate threshold.

7. The battery of claim 5, wherein the one or more processors are further configured to:
obtain a voltage of the electrical energy storage unit of the battery in response to determining that the voltage change rate of the battery is greater than or equal to a change-rate threshold; and
determine whether the battery is damaged or abnormal according to the voltage of the electrical energy storage unit and the voltage change rate of the battery.

8. The battery of claim 7, wherein:
the change-rate threshold is a first change-rate threshold; and
the one or more processors are further configured to:
determine the battery as in a normal working state in response to determining that the voltage of the electrical energy storage unit is less than a first voltage threshold; or
determine the battery as being damaged or abnormal in response to determining that the voltage of the electrical energy storage unit is greater than or equal to the first voltage threshold and less than a second voltage threshold, the second voltage threshold being greater than the first voltage threshold; or
determine the battery as being damaged or abnormal in response to determining that the voltage of the electrical energy storage unit is greater than or equal to the second voltage threshold and the voltage change rate of the battery is greater than or equal to a second change-rate threshold, the second change-rate threshold being greater than the first change-rate threshold; or
determine the battery as in the normal working state in response to determining that the voltage of the electrical energy storage unit is greater than or equal to the second voltage threshold and the voltage change rate of the battery is less than the second change-rate threshold.

9. The battery of claim 1, wherein:
the one or more electrical parameters of the battery include a self-discharge current; and
the one or more processors are further configured to:
determine the battery as being damaged or abnormal in response to determining that the self-discharge current is greater than or equal to a current threshold; or
determine the battery as in a normal working state in response to determining that the self-discharge current is less than the current threshold.

10. The battery of claim 1, wherein:
the one or more electrical parameters of the battery include a self-discharge current; and
the one or more processors are further configured to:
obtain a battery capacity and a state of charge (SoC) change rate of the battery; and
obtain the self-discharge current according to the battery capacity and the SoC change rate of the battery.

11. The battery of claim 10, wherein the self-discharge current is proportional to a product of the SoC change rate of the battery and the battery capacity.

12. The battery of claim 1, wherein the safe state includes at least one of a state in which a state of charge (SoC) of the battery is less than a preset SoC or a state in which a voltage of the battery is less than a preset voltage.

13. A mobile platform comprising:
a motor; and
a battery configured to power the motor, the battery including:
a housing;
an electrical energy storage unit mounted inside the housing; and
a battery control system electrically coupled to the electrical energy storage unit to control charge and discharge of the electrical energy storage unit, the battery control system including one or more processors configured to:
obtain one or more electrical parameters of the battery in a storage state;
determine whether the battery is damaged or abnormal according to the one or more electrical parameters of the battery; and
automatically discharge the battery to a safe state in response to determining that the battery is damaged or abnormal.

14. The mobile platform of claim 13, wherein the mobile platform includes at least one of a gimbal, an electric car, or an unmanned aerial vehicle (UAV).

15. The mobile platform of claim 13, wherein the battery control system further includes:
a data collector communicatively coupled to the one or more processors and configured to:
collect the one or more electrical parameters of the battery in the storage state; and
send the one or more electrical parameters to the one or more processors.

16. The mobile platform of claim 13, wherein the one or more electrical parameters of the battery include at least one of a voltage of the battery, a voltage of the electrical energy storage unit of the battery, a state of charge (SoC) of the electrical energy storage unit of the battery, an SoC of the battery, or a self-discharge current.

17. The mobile platform of claim 13, wherein the one or more processors are further configured to:
obtain change information of the one or more electrical parameters of the battery according to the one or more electrical parameters of the battery; and
determine whether the battery is damaged or abnormal according to the change information of the one or more electrical parameters of the battery.

18. The mobile platform of claim 13, wherein:
the one or more electrical parameters of the battery include a self-discharge current; and
the one or more processors are further configured to:
determine the battery as being damaged or abnormal in response to determining that the self-discharge current is greater than or equal to a current threshold; or
determine the battery as in a normal working state in response to determining that the self-discharge current is less than the current threshold.

19. The mobile platform of claim 13, wherein:
the one or more electrical parameters of the battery include a self-discharge current; and
the one or more processors are further configured to:
obtain a battery capacity and a state of charge (SoC) change rate of the battery; and
obtain the self-discharge current according to the battery capacity and the SoC change rate of the battery.

20. The mobile platform of claim 13, wherein the safe state includes at least one of a state in which a state of charge (SoC) of the battery is less than a preset SoC or a state in which a voltage of the battery is less than a preset voltage.
